(19) United States
(12) Patent Application Publication
(10) Pub. No.: US 2026/0223409 A1
(43) Pub. Date: Jul. 30, 2026

(54) THIN FILM TRANSISTOR AND DISPLAY PANEL

(71) Applicant: Guangzhou China Star Optoelectronics Semiconductor Display Technology Co., Ltd., Guangzhou (CN)

(72) Inventors: Bin ZHAO, Guangzhou (CN); Weiran CAO, Guangzhou (CN); Xiaolin YAN, Guangzhou (CN); Jun ZHAO, Guangzhou (CN); Mingjiue YU, Guangzhou (CN); Xiaoxing ZHANG, Guangzhou (CN)

(73) Assignee: Guangzhou China Star Optoelectronics Semiconductor Display Technology Co., Ltd., Guangzhou (CN)

(21) Appl. No.: 19/243,000

(22) Filed: Jun. 19, 2025

(30) Foreign Application Priority Data
Jan. 24, 2025 (CN) 202510122786.2

(51) Int. Cl. H10D 30/67

(52) U.S. Cl. CPC H10D 30/6755

(57) ABSTRACT

A thin film transistor and a display panel are provided. The thin film transistor includes an active layer including a first semiconductor layer, the first semiconductor layer includes a metal oxide conductor material and a metal element M doped in the metal oxide conductor material, and the metal element M is at least one element selected from the group consisting of lanthanide elements and transition elements.

### CROSS-REFERENCE TO RELATED APPLICATION

This application claims priority to and the benefit of Chinese Patent Application No. 202510122786.2, filed on Jan. 24, 2025, the disclosure of which is incorporated herein by reference in its entirety.

### TECHNICAL FIELD

The present disclosure relates to the field of display, and in particular, to a thin film transistor and a display panel.

### BACKGROUND

Oxide semiconductor thin film transistors have attracted wide attention because of their high electron mobility, excellent uniformity, good transparency, and low cost. At present, IGZO (Indium Gallium Zinc Oxide) semiconductor materials have already entered the mass production stage, and various research institutions are dedicated to developing oxide semiconductor materials having high mobility as the next-generation replacements for IGZO materials.

### SUMMARY

In a first aspect, some embodiments of the present disclosure provide a thin film transistor including an active layer, the active layer includes a first semiconductor layer, and the first semiconductor layer includes a metal oxide conductor material and a metal element M doped in the metal oxide conductor material; and
the metal element M is at least one element selected from the group consisting of lanthanide elements and transition elements.

In a second aspect, some embodiments of the present disclosure provide a display panel including the thin film transistor described above.

### BRIEF DESCRIPTION OF THE DRAWINGS

In order to explain the technical solutions in the embodiments of the present disclosure more clearly, a brief introduction to the drawings required for the description of the embodiments is provided below. Apparently, the drawings in the following description are merely some embodiments of the present disclosure. For those skilled in the art, other drawings can be obtained from these drawings without any inventive effort.

In order to more fully understand the present disclosure and its beneficial effects, the following explanation will be provided in conjunction with the accompanying drawings, where the same reference numerals in the following descriptions represent the same components.

FIG. 1 is a first schematic cross-sectional structural diagram of a thin film transistor according to some embodiments of the present disclosure.

FIG. 2 is a first schematic cross-sectional structural diagram of an active layer according to some embodiments of the present disclosure.

FIG. 3 is a second schematic cross-sectional structural diagram of the active layer according to some embodiments of the present disclosure.

FIG. 4 is a third schematic cross-sectional structural diagram of the active layer according to some embodiments of the present disclosure.

FIG. 5 is a second schematic cross-sectional structural diagram of the thin film transistor according to some embodiments of the present disclosure.

FIG. 6 is a third schematic cross-sectional structural diagram of the thin film transistor according to some embodiments of the present disclosure.

Reference numerals: 1 (1′, 1″), thin film transistor; 2, active layer; 3, first semiconductor layer; 4, second semiconductor layer; 5, gate; 6, gate insulating layer; 7, source; 8, drain; 9, substrate; 10, passivation layer; 11, light-shielding layer; 12, blocking layer; 13, interlayer insulating layer; and 14, etch stop layer.

### DETAILED DESCRIPTION

Technical solutions in the embodiments of the present disclosure will be clearly and completely described with reference to the drawings.

Generally, a thin film transistor with high mobility is obtained by using an oxide semiconductor with high electron concentration. Common methods include increasing the content of indium (In) in the oxide semiconductor, or doping other materials (such as Sn) that can provide more electrons into an oxide semiconductor target material. However, although conventional semiconductor materials with high mobility can achieve high mobility, the light stability of these materials is poor, which may lead to a photogenerated carrier problem of devices, affecting the performance and stability of the devices.

In view of the above technical problem, the embodiments of the present disclosure provide a thin film transistor and a display panel, where a metal oxide conductor material is modified from having characteristics of a conductor to characteristics of a semiconductor by doping a metal element M to serve as an active layer material of the thin film transistor, thereby obtaining a high-mobility thin film transistor. At the same time, the light stability of the thin film transistor can be enhanced by doping the metal element M. Specific reference is made to the description of the following embodiments.

As shown in FIG. 1, some embodiments of the present disclosure provide a thin film transistor 1 including an active layer 2. The active layer 2 includes a first semiconductor layer 3, and the first semiconductor layer 3 includes a metal oxide conductor material and a metal element M doped in the metal oxide conductor material. The metal element M is at least one element selected from the group consisting of lanthanide elements and transition elements.

It can be understood that the metal oxide conductor material is the main material of the first semiconductor layer 3. By doping a specific proportion of the metal element M into the metal oxide conductor material, the metal oxide conductor material is modified from having the characteristics of the conductor to the characteristics of the semiconductor while maintaining high mobility, so as to obtain the first semiconductor layer 3 with high mobility, thus enabling the active layer 2 to have high mobility.

In some embodiments, a molar proportion (i.e., molar percentage) of the metal element M in the first semiconductor layer 3 is greater than or equal to 0.1% and less than or equal to 10%.

It can be understood that, by controlling the molar proportion of the metal element M in the first semiconductor layer 3 in the range of 0.1% to 10%, the metal oxide conductor material can be effectively modified from having the characteristics of the conductor to the characteristics of the semiconductor.

In some embodiments, the metal element M is at least one element selected from the group consisting of the lanthanide elements.

In a specific embodiment, the metal element M is at least one element selected from the group consisting of a praseodymium (Pr) element, a terbium (Tb) element, and a dysprosium (Dy) element, but is not limited thereto.

Since the praseodymium element, the terbium element, and the dysprosium element have the effect of suppressing carriers, doping at least one of these elements into the metal oxide conductor material helps to modify the metal oxide conductor material into a semiconductor material.

In some embodiments, the metal element M is at least one element selected from the group consisting of the transition elements.

In a specific embodiment, the metal element M is at least one element selected from the group consisting of a zirconium (Zr) element, a tantalum (Ta) element, and a hafnium (Hf) element, but is not limited thereto.

In a specific embodiment, the metal element M is at least one element selected from the group consisting of the tantalum element and the hafnium element, but is not limited thereto.

As the praseodymium element, the terbium element, and the dysprosium element, the zirconium element has the effect of suppressing carriers. Therefore, doping the zirconium element into the metal oxide conductor material helps modify the metal oxide conductor material into a semiconductor material.

The tantalum element and the hafnium element are beneficial to increasing the band gap width, and at the same time, the tantalum element can maintain a high carrier concentration. Therefore, doping the tantalum element and the hafnium element into the metal oxide conductor material can improve the light stability of the active layer 2 (or the thin film transistor 1) and make the thin film transistor 1 have high mobility.

It should be noted that the tantalum element is advantageous in maintaining a high carrier concentration, indicating that the carrier concentration in the first semiconductor layer 3 is maintained at a high level on the basis that the first semiconductor layer 3 has the characteristics of the semiconductor.

It can be understood that the improvement of the light stability of the active layer 2 can improve the photogenerated carrier problem of the active layer 2, and thus the performance and reliability of the thin film transistor 1 can be improved.

Due to the poor light stability of conventional high-mobility semiconductor materials, the photogenerated current of the thin film transistor 1 is relatively large, which may affect the performance and reliability of the thin film transistor 1. In the embodiments of the present disclosure, by doping the tantalum element and the hafnium element, the light stability of the active layer 2 can be effectively improved, and the performance and reliability of the thin film transistor 1 can be enhanced.

In some embodiments, the metal element M may be at least one element selected from the group consisting of a praseodymium element, a terbium element, a dysprosium element, a zirconium element, a tantalum element, and a hafnium element. For example, the metal element M is at least one element selected from the group consisting of the praseodymium element, the terbium element, and the dysprosium element, and the group consisting of the zirconium element, the tantalum element, and the hafnium element. This solution can improve the light stability of the active layer 2 while obtaining the active layer 2 with high mobility.

In some embodiments, the metal oxide conductor material is TCO (transparent conductive oxide).

It can be understood that the transparent conductive oxide is a thin film material with high transmittance and low resistivity in the visible light spectrum range (380 nm<λ<780 nm). TCO thin film materials mainly include oxides such as CdO, In₂O₃, SnO₂, and ZnO, as well as composite multi-component compound semiconductor materials thereof. The quantification index is that the visible light source transmittance at 550 nanometers is greater than 80%, and the surface impedance is less than 1000 Ω/m².

In a specific embodiment, the metal oxide conductor material includes at least one of indium tin oxide (ITO), indium oxide (InO), or indium zinc oxide (IZO), but is not limited thereto.

In some embodiments, the metal oxide conductor material is indium tin oxide.

In some embodiments, a molar proportion of indium element in the first semiconductor layer 3 is greater than or equal to 50% and less than or equal to 90%, and a molar proportion of tin element in the first semiconductor layer 3 is greater than or equal to 0.1% and less than or equal to 10%. Maintaining the content of the indium element at a high level, so that electron in the first semiconductor layer 3 has a relatively high concentration, which is conducive to improving the mobility of the thin film transistor 1, thereby obtaining the devices with high mobility.

In some embodiments, a carrier concentration of the first semiconductor layer 3 is greater than or equal to 1E14 cm⁻³ and less than or equal to 5E19 cm⁻³.

It should be noted that, 1E14 cm⁻³ refers to 1×10¹⁴ cm⁻³, and 5E19 cm⁻³ refers to 5×10¹⁹ cm⁻³.

It can be understood that when the carrier concentration of the film layer is too high, for example, the carrier concentration of the film layer is in the range of 1E20 cm⁻³ to 1E21 cm⁻³, the film layer has the characteristics of the conductor. In the embodiments of the present disclosure, by doping the metal element M in the metal oxide conductor material with high carrier concentration, the carrier concentration can be reduced, so that the semiconductor treatment of the conductor material can be achieved.

In some embodiments, the active layer 2 is an N-type semiconductor layer, and thus, the carrier concentration refers to the concentration of electron.

In some embodiments, a resistance of the first semiconductor layer 3 is greater than or equal to 1 E4 Ω/m² and less than or equal to 1 E10 Ω/m².

The resistance described above refers to a square resistance, that is, a resistance value per unit area. For example, 1E4 Ω/m² refers to 1×10⁴ Ω/m², and 1E10 Ω/m² refers to 1×10¹⁰ Ω/m².

It can be understood that when the resistance of a film layer is small, the film layer exhibits the characteristics of the conductor. Therefore, the resistance of the first semiconductor layer 3 provided in the embodiments of the present disclosure is in the range of 1E4 Ω/m² to 1E10 Ω/m², indicating that the first semiconductor layer 3 has the characteristics of the semiconductor.

In some embodiments, a Hall mobility of the first semiconductor layer 3 is greater than or equal to 30 cm²/(V·s) and less than or equal to 70 cm²/(V·s).

It is understood that when the Hall mobility of a film layer is too high, for example, the Hall mobility of the film layer is greater than 100 cm²/(V·s), the film layer has the characteristics of the conductor. Therefore, the Hall mobility of the first semiconductor layer 3 provided in the embodiments of the present disclosure is in the range of 30 cm²/(V·s) to 70 cm²/(V·s), indicating that the first semiconductor layer 3 has the characteristics of the semiconductor.

Generally, the Hall mobility of the IGZO semiconductor layer is 10 cm²/(V·s). Obviously, the Hall mobility of the first semiconductor layer provided in the embodiments of the present disclosure is much greater than the Hall mobility of the IGZO semiconductor layer.

In some embodiments, the active layer 2 is a single-layer structure. That is, the active layer 2 is only composed of the first semiconductor layer 3, and at this time, the entire active layer 2 has high mobility.

When the active layer 2 is the single-layer structure, a thickness of the first semiconductor layer 3 (the active layer 2) is greater than or equal to 100 Å and less than or equal to 500 Å. By controlling the thickness of the first semiconductor layer 3 in this range, negative bias of the threshold voltage Vth due to excessive thickness of the active layer 2 can be avoided, and the stability of the thin film transistor 1 can be improved.

In other embodiments, the active layer 2 may be a multilayer structure. For example, the active layer 2 is a double-layer or three-layer structure, but is not limited thereto. When the active layer 2 is the multilayer structure, materials of any two adjacent semiconductor layers are different.

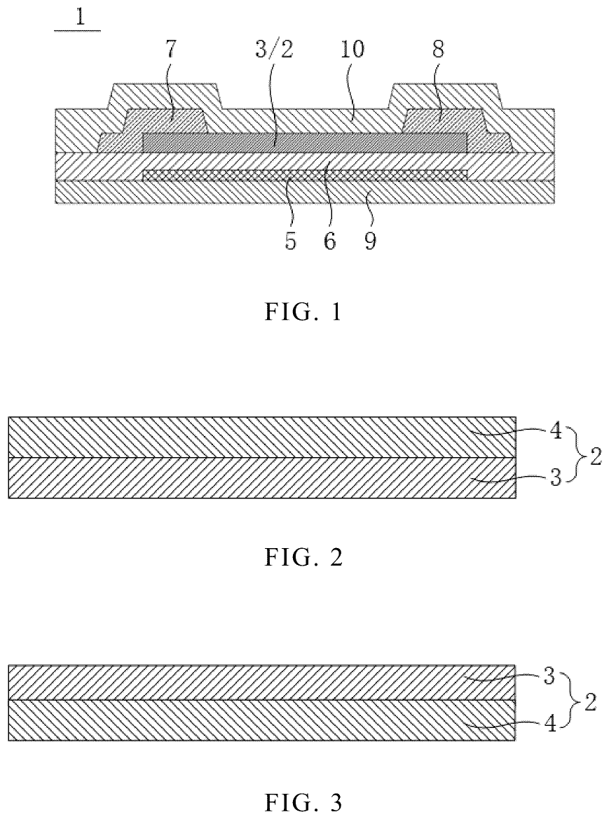

In some embodiments, as shown in FIGS. 2 to 4, the active layer 2 further includes a second semiconductor layer 4 stacked with the first semiconductor layer 3, and the second semiconductor layer 4 includes a metal oxide semiconductor material.

In some embodiments, the Hall mobility of the second semiconductor layer 4 is less than the Hall mobility of the first semiconductor layer 3.

It can be understood that, when the Hall mobility of the first semiconductor layer 3 is greater than the Hall mobility of the second semiconductor layer 4, it is conducive to improving the overall mobility of the active layer 2 by applying the two to the active layer 2.

In some embodiments, as shown in FIG. 2 and FIG. 3, the active layer 2 includes the first semiconductor layer 3 and the second semiconductor layer 4 disposed on a side of the first semiconductor layer 3, and the second semiconductor layer 4 includes a metal oxide semiconductor material. That is, the active layer 2 is a double-layer structure.

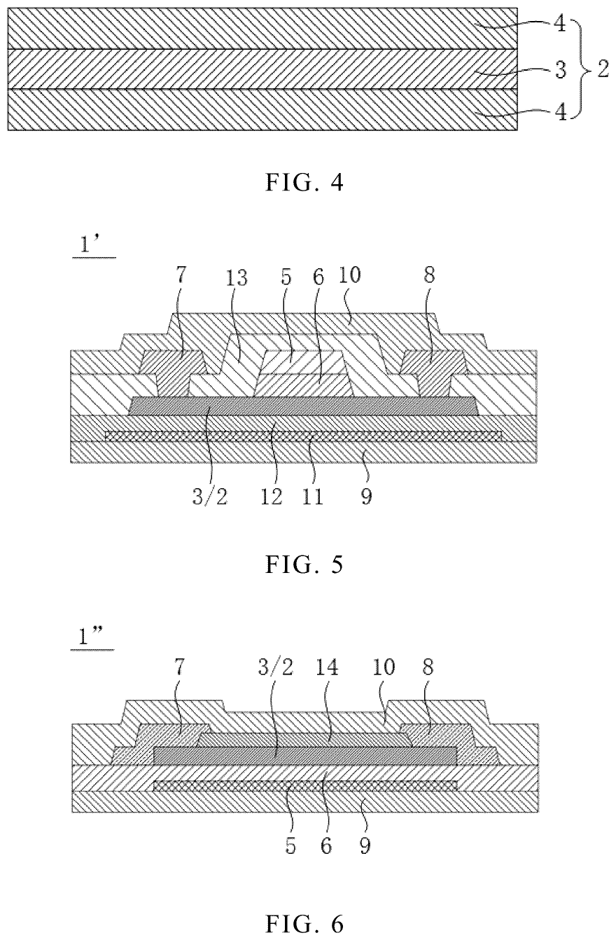

In another specific embodiment, as shown in FIG. 4, the active layer 2 includes at least two second semiconductor layers 4, the first semiconductor layer 3 is disposed between the two second semiconductor layers 4, and the second semiconductor layer 4 includes a metal oxide semiconductor material. That is, at this point, the active layer 2 is at least a three-layer structure.

In some embodiments, when the active layer 2 is a two-layer structure or a three-layer structure composed of the first semiconductor layer 3 and the second semiconductor layer 4, the thickness of the first semiconductor layer 3 is greater than or equal to 100 Å and less than or equal to 400 Å, and the thickness of the second semiconductor layer 4 is greater than or equal to 100 Å and less than or equal to 300 Å.

In the embodiments of the present disclosure, the active layer 2 is provided as a multilayer structure. On the one hand, by setting at least one layer of the multilayer structure as the first semiconductor layer 3 with high mobility, it is conducive to reducing the overall thickness of the active layer 2 while improving the overall mobility of the active layer 2, thereby avoiding negative bias of the threshold voltage Vth caused by excessive thickness of the active layer 2, and further improving the stability of the thin film transistor 1. On the other hand, since the second semiconductor layer 4 with low mobility in the active layer 2 is in contact with other film layers, it is conducive to reducing defects at the contact interface between the active layer 2 and film layers adjacent thereto, so that the stability of the thin film transistor 1 can be improved. Moreover, it can prevent the threshold voltage Vth of the thin film transistor 1 from becoming relatively non-negative biased, thereby further improving the performance and reliability of the thin film transistor 1.

In a specific embodiment, the metal oxide semiconductor material includes IGZO. That is, the second semiconductor layer 4 may be a conventional metal oxide semiconductor material.

Since IGZO has been mass-produced and can improve the defects at the contact interface, the application of IGZO in the active layer 2 in conjunction with the first semiconductor layer 3 can improve the stability and reliability of the thin film transistor 1 while improving the mobility of the thin film transistor 1.

In some embodiments, the thin film transistor 1 further includes a gate 5, a gate insulating layer 6, a source 7, and a drain 8. The gate 5 is disposed on a side of the active layer 2 and in alignment with the active layer 2. A part of the gate insulating layer 6 is disposed between the gate 5 and the active layer 2. The source 7 and the drain 8 are disposed on a side of the active layer 2 and electrically connected to opposite sides of the active layer 2, respectively.

In a specific embodiment, as shown in FIG. 1, the thin film transistor 1 further includes a substrate 9 and a passivation layer 10. The gate 5 is disposed on the substrate 9, and the gate insulating layer 6 covers the substrate 9 and the gate 5. The active layer 2 is disposed on the gate insulating layer 6, and the active layer 2 is disposed in alignment with the gate 5. The source 7 and the drain 8 cover opposite sides of the active layer 2, respectively. The passivation layer 10 covers the gate insulating layer 6, the source 7, the drain 8, and part of the active layer 2.

It can be understood that the thin film transistor 1 provided in the embodiments of the present disclosure is a BCE (Back Channel Etch) type thin film transistor. By providing the gate 5 below the active layer 2, the gate 5 can provide a light-shielding effect, avoiding the setting of an additional light-shielding layer below the active layer 2, thereby simplifying the structure of the thin film transistor 1.

Since the embodiments of the present disclosure only improve the material of the active layer 2, the thin film transistor 1 provided by the embodiments of the present disclosure can be produced using a production line in a mass-production mode. For example, in the process of preparing the active layer 2, the metal element M can be directly added to raw materials of target material for the metal oxide conductor material, and a metal oxide target material containing the metal element M and being uniformly mixed can be obtained after sintering. After the active layer 2 is formed by the metal oxide target material containing the metal element M, no further doping process is required, so that the preparation process of the active layer 2 is simplified, the manufacturing efficiency of the active layer 2 is improved, and the manufacturing cost of the active layer 2 is reduced.

When the active layer 2 is a two-layer structure, the second semiconductor layer 4 may be disposed between the first semiconductor layer 3 and the passivation layer 10, or between the first semiconductor layer 3 and the gate insulating layer 6. When the second semiconductor layer 4 is disposed between the first semiconductor layer 3 and the passivation layer 10, defects at the contact interface between the active layer 2 and the passivation layer 10 can be reduced. When the second semiconductor layer 4 is disposed between the first semiconductor layer 3 and the gate insulating layer 6, defects at the contact interface between the active layer 2 and the gate insulating layer 6 can be reduced. By reducing the defects at the contact interface between the active layer 2 and the film layer adjacent thereto, the stability of the thin film transistor 1 can be improved. Moreover, it can prevent the threshold voltage Vth of the thin film transistor 1 from becoming relatively non-negative biased, thereby enhancing the performance and reliability of the thin film transistor 1.

When the active layer 2 is a three-layer structure, one second semiconductor layer 4 is disposed between the first semiconductor layer 3 and the passivation layer 10, and another second semiconductor layer 4 is disposed between the first semiconductor layer 3 and the gate insulating layer 6. This solution can simultaneously reduce the defects at the contact interface between the active layer 2 and the passivation layer 10, and between the active layer 2 and the gate insulating layer 6, thereby further improving the stability of the thin film transistor 1. Moreover, it can prevent the threshold voltage Vth of the thin film transistor 1 from becoming relatively non-negative biased, thereby further improving the performance and reliability of the thin film transistor 1.

In the embodiments of the present disclosure, the metal oxide conductor material is doped with a specific proportion of the metal element M, and the metal element M is at least one element selected from the group consisting of lanthanide elements and transition elements, so that the metal element M has at least the effect of suppressing carriers, and thus, the metal oxide conductor material can be modified from having the characteristics of the conductor to the characteristics of the semiconductor while maintaining high mobility. Therefore, when the metal oxide conductor material doped with an appropriate amount of the metal element M is applied to the active layer 2 of the thin film transistor 1, the active layer 2 has the characteristics of the semiconductor and high mobility, so that the thin film transistor 1 has high mobility. At the same time, the doping of some metal elements M (such as tantalum element and hafnium element) is conducive to increasing the band gap width and maintaining a high carrier concentration, thereby improving the light stability and mobility of the thin film transistor 1.

As shown in FIG. 5, some embodiments of the present disclosure provide a thin film transistor 1′, which is different from the thin film transistor 1 provided in the above-mentioned embodiments in that the thin film transistor 1′ is a top gate self-aligned type thin film transistor, and the thin film transistor 1′ further includes a light-shielding layer 11, a blocking layer 12, and an interlayer insulating layer 13. The light-shielding layer 11 is disposed on the substrate 9. The blocking layer 12 covers the substrate 9 and the light-shielding layer 11. The active layer 2 is disposed on the blocking layer 12 and in alignment with the light-shielding layer 11. The gate insulating layer 6 and the gate 5 are sequentially stacked on the active layer 2. A side of the gate insulating layer 6 away from the active layer 2 has the same shape and area as a side of the gate 5 close to the active layer 2. The interlayer insulating layer 13 covers the blocking layer 12, the active layer 2, the gate insulating layer 6, and the gate 5. The source 7 and the drain 8 are disposed on the interlayer insulating layer 13, and electrically connected to the active layer 2 through two through holes penetrating the interlayer insulating layer 13, respectively. The passivation layer 10 covers the interlayer insulating layer 13, the source 7, and the drain 8.

The active layer 2 provided in the embodiments of the present disclosure can be prepared by the same method as in the above-mentioned embodiments, and will not be repeated here.

When the active layer 2 is a two-layer structure, the second semiconductor layer 4 may be disposed between the first semiconductor layer 3 and the gate insulating layer 6 and the interlayer insulating layer 13, or disposed between the first semiconductor layer 3 and the blocking layer 12. When the second semiconductor layer 4 is disposed between the first semiconductor layer 3 and the gate insulating layer 6 and the interlayer insulating layer 13, defects at the contact interface between the active layer 2 and the gate insulating layer 6 and the interlayer insulating layer 13 can be reduced. When the second semiconductor layer 4 is disposed between the first semiconductor layer 3 and the blocking layer 12, defects at the contact interface between the active layer 2 and the blocking layer 12 can be reduced. This solution can improve the stability of the thin film transistor 1′. Moreover, it can prevent the threshold voltage Vth of the thin film transistor 1′ from becoming relatively non-negative biased, thereby improving the performance and reliability of the thin film transistor 1′.

When the active layer 2 is a three-layer structure, one second semiconductor layer 4 is disposed between the first semiconductor layer 3 and the gate insulating layer 6 and the interlayer insulating layer 13, and another second semiconductor layer 4 is disposed between the first semiconductor layer 3 and the blocking layer 12. This solution can simultaneously reduce the defects at the contact interface between the active layer 2 and the gate insulating layer 6, and reduce the defects at the contact interface between the interlayer insulating layer 13 and the blocking layer 12, thereby further improving the stability of the thin film transistor 1′. Moreover, it can prevent the threshold voltage Vth of the thin film transistor 1′ from becoming relatively non-negative biased, thereby further improving the performance and reliability of the thin film transistor 1′.

In the embodiments of the present disclosure, the metal oxide conductor material is doped with a specific proportion of the metal element M, and the metal element M is at least one element selected from the group consisting of lanthanide elements and transition elements, so that the metal element M has at least the effect of suppressing carriers, and thus, the metal oxide conductor material can be modified from having the characteristics of the conductor to the characteristics of the semiconductor while maintaining high mobility. Therefore, when the metal oxide conductor material doped with an appropriate amount of the metal element M is applied to the active layer 2 of the thin film transistor 1′, the active layer 2 has the characteristics of the semiconductor and high mobility, so that the thin film transistor 1′ has high mobility. At the same time, the doping of some metal elements M (such as tantalum element and hafnium element) is conducive to increasing the band gap width and maintaining a high carrier concentration, thereby improving the light stability and mobility of the thin film transistor 1′.

As shown in FIG. 6, some embodiments of the present disclosure provide a thin film transistor 1″, which is different from the thin film transistor 1 provided in the above-mentioned embodiments in that the thin film transistor 1″ is an etch stop type thin film transistor, and the thin film transistor 1″ further includes an etch stop layer 12 disposed on the active layer 2 and corresponding to a channel region of the active layer 2. The source 7 and the drain 8 cover opposite sides of the active layer 2, respectively, and further cover edges of the etch stop layer 12. The passivation layer 10 covers the gate insulating layer 6, the source 7, the drain 8, and the etch stop layer 12.

Similarly to the above-mentioned embodiments, by providing the gate 5 below the active layer 2, the gate 5 can provide a light-shielding effect, avoiding the setting of an additional light-shielding layer below the active layer 2, thereby simplifying the structure of the thin film transistor 1″.

The active layer 2 in the embodiments of the present disclosure can be prepared by the same method as in the above-mentioned embodiments, and will not be repeated here.

When the active layer 2 is a two-layer structure, the second semiconductor layer 4 may be disposed between the first semiconductor layer 3 and the etch stop layer 12, or between the first semiconductor layer 3 and the gate insulating layer 6. When the second semiconductor layer 4 is disposed between the first semiconductor layer 3 and the etch stop layer 12, defects at the contact interface between the active layer 2 and the etch stop layer 12 can be reduced. When the second semiconductor layer 4 is disposed between the first semiconductor layer 3 and the gate insulating layer 6, defects at the contact interface between the active layer 2 and the gate insulating layer 6 can be reduced. This solution can improve the stability of the thin film transistor 1″. Moreover, it can prevent the threshold voltage Vth of the thin film transistor 1″ from becoming relatively non-negative biased, thereby improving the performance and reliability of the thin film transistor 1″.

When the active layer 2 is a three-layer structure, one second semiconductor layer 4 is disposed between the first semiconductor layer 3 and the etch stop layer 12, and another second semiconductor layer 4 is disposed between the first semiconductor layer 3 and the gate insulating layer 6. This solution can simultaneously reduce defects at the contact interface between the active layer 2 and the etching blocking layer 12, and reduce defects at the contact interface between the active layer 2 and the gate insulating layer 6, thereby further improving the stability of the thin film transistor 1″. Moreover, it can prevent the threshold voltage Vth of the thin film transistor 1″ from becoming relatively non-negative biased, thereby further improving the performance and reliability of the thin film transistor 1″.

In the embodiments of the present disclosure, the metal oxide conductor material is doped with a specific proportion of the metal element M, and the metal element M is at least one element selected from the group consisting of lanthanide elements and transition elements, so that the metal element M has at least the effect of suppressing carriers, and thus, the metal oxide conductor material can be modified from having the characteristics of the conductor to the characteristics of the semiconductor while maintaining high mobility. Therefore, when the metal oxide conductor material doped with an appropriate amount of the metal element M is applied to the active layer 2 of the thin film transistor 1″, the active layer 2 has the characteristics of the semiconductor and high mobility, so that the thin film transistor 1″ has high mobility. At the same time, the doping of some metal elements M (such as tantalum element and hafnium element) is conducive to increasing the band gap width and maintaining a high carrier concentration, thereby improving the light stability and mobility of the thin film transistor 1″.

Some embodiments of the present disclosure further provide a display panel, which includes the thin film transistor as described in any of the above-mentioned embodiments. The embodiments of the present disclosure do not limit the specific type of the display panel.

In some embodiments, the display panel includes an array substrate in which the thin film transistor is provided, but is not limited thereto.

It can be understood that mobility is one of the important indicators to measure the performance of the thin film transistor. It determines the moving speed of charges in the thin film transistor. Therefore, high mobility means relatively fast response speed and high operation efficiency, which can improve the overall performance of electronic devices. At the same time, the greater the mobility, the smaller the resistivity, and the smaller the power consumption when passing through the same current, which means that the device having a thin film transistor with high mobility can complete the same task with relatively low power consumption, thereby reducing energy waste and heat generation. Moreover, the mobility directly affects the switching speed and cutoff frequency of the turn-on and turn-off of the thin film transistor, therefore, the thin film transistor with high mobility can shorten the time for minority carriers to cross the base region, thereby improving the switching speed of the turn-on and turn-off and frequency response characteristics of the thin film transistor.

In the embodiments of the present disclosure, since the thin film transistor provided in the above-mentioned embodiments has high mobility and light stability, it is beneficial to improving the response speed, operation efficiency and stability of the display panel. Moreover, the power consumption of the display panel can be reduced.

In the description of the present disclosure, the terms “first” and “second” are used merely for descriptive purposes and should not be construed as indicating or implying relative importance, nor as implicitly specifying the quantity of the technical features referred to. Therefore, the features defined as “first” and “second” may explicitly or implicitly include one or more features. In the description of the present disclosure, the terms “a plurality of” and “more” refer to two or more than two, unless otherwise specified.

In the above-mentioned embodiments, the description of each embodiment has its own emphasis, and for parts not described in detail in a certain embodiment, please refer to the relevant description of other embodiments.

The embodiments, examples, and related technical features of the present disclosure may be combined and replaced with each other without conflict.

The above are merely preferred embodiments of the present disclosure, and do not limit the present disclosure in any form. Any simple modifications, equivalent changes, and modifications made to the above embodiments according to the technical essence of the present disclosure without departing from the contents of the technical solutions of the present disclosure still fall within the scope of the technical solutions of the present disclosure.

What is claimed is:

1. A thin film transistor comprising an active layer, wherein the active layer comprises a first semiconductor layer, the first semiconductor layer comprises a metal oxide conductor material and a metal element M doped in the metal oxide conductor material; and
wherein the metal element M is at least one element selected from a group consisting of lanthanide elements and transition elements.

2. The thin film transistor according to claim 1, wherein the metal element M is at least one element selected from a group consisting of a praseodymium element, a terbium element, and a dysprosium element of the lanthanide elements.

3. The thin film transistor according to claim 1, wherein the metal element M is at least one element selected from a group consisting of a zirconium element, a tantalum element, and a hafnium element of the transition elements.

4. The thin film transistor according to claim 1, wherein the metal element M is at least one element selected from a group consisting of a praseodymium element, a terbium element, a dysprosium element of the lanthanide elements, and a group consisting of a zirconium element, a tantalum element, and a hafnium element of the transition elements.

5. The thin film transistor according to claim 1, wherein the metal oxide conductor material comprises at least one of indium tin oxide, indium oxide, or indium zinc oxide.

6. The thin film transistor according to claim 1, wherein a molar proportion of the metal element M in the first semiconductor layer is greater than or equal to 0.1% and less than or equal to 10%.

7. The thin film transistor according to claim 5, wherein a molar proportion of an indium element in the first semiconductor layer is greater than or equal to 50% and less than or equal to 90%, and a molar proportion of a tin element in the first semiconductor layer is greater than or equal to 0.1% and less than or equal to 10%.

8. The thin film transistor according to claim 1, wherein a carrier concentration of the first semiconductor layer is greater than or equal to 1E14 cm⁻³ and less than or equal to 5E19 cm⁻³.

9. The thin film transistor according to claim 1, wherein a resistance of the first semiconductor layer is greater than or equal to 1E4 Ω/m² and less than or equal to 1E10 Ω/m².

10. The thin film transistor according to claim 1, wherein a Hall mobility of the first semiconductor layer is greater than or equal to 30 cm²/(V·s) and less than or equal to 70 cm²/(V·s).

11. The thin film transistor according to claim 1, wherein the active layer further comprises a second semiconductor layer stacked with the first semiconductor layer, and the second semiconductor layer comprises a metal oxide semiconductor material.

12. The thin film transistor according to claim 11, wherein a Hall mobility of the second semiconductor layer is less than a Hall mobility of the first semiconductor layer.

13. The thin film transistor according to claim 12, wherein the metal oxide semiconductor material comprises indium gallium zinc oxide.

14. The thin film transistor according to claim 1, wherein the active layer comprises two second semiconductor layers, the first semiconductor layer is disposed between the two second semiconductor layers, and each of the two second semiconductor layers comprises a metal oxide semiconductor material.

15. The thin film transistor according to claim 14, wherein a Hall mobility of each of the two second semiconductor layers is less than a Hall mobility of the first semiconductor layer.

16. The thin film transistor of claim 1, further comprising a gate, a gate insulating layer, a source, and a drain, wherein the gate is disposed on a side of the active layer and in alignment with the active layer, a part of the gate insulating layer is disposed between the gate and the active layer, and the source and the drain are disposed on a side of the active layer and electrically connected to opposite sides of the active layer, respectively; and
wherein the thin film transistor comprises any one of a top gate self-aligned type thin film transistor, a back channel etch type thin film transistor, and an etch stop type thin film transistor.

17. A display panel comprising a thin film transistor comprising an active layer, wherein the active layer comprises a first semiconductor layer, the first semiconductor layer comprises a metal oxide conductor material and a metal element M doped in the metal oxide conductor material, and the metal element M is at least one element selected from a group consisting of lanthanide elements and transition elements.

18. The display panel according to claim 17, wherein the metal element M is at least one element selected from a group consisting of a praseodymium element, a terbium element, a dysprosium element, a zirconium element, a tantalum element, and a hafnium element.

19. The display panel according to claim 17, wherein the metal oxide conductor material comprises at least one of indium tin oxide, indium oxide, or indium zinc oxide.

20. The display panel according to claim 17, wherein a molar proportion of the metal element M in the first semiconductor layer is greater than or equal to 0.1% and less than or equal to 10%;
a carrier concentration of the first semiconductor layer is greater than or equal to 1E14 cm⁻³ and less than or equal to 5E19 cm⁻³;
a resistance of the first semiconductor layer is greater than or equal to 1E4 Ω/m² and less than or equal to 1E10 Ω/m²; and
a Hall mobility of the first semiconductor layer is greater than or equal to 30 cm²/(V·s) and less than or equal to 70 cm²/(V·s).
